(19) United States
(12) Patent Application Publication
(10) Pub. No.: US 2007/0138540 A1
(43) Pub. Date: Jun. 21, 2007

(54) Group III nitride based compound semiconductor optical device

(75) Inventors: Toshiya Uemura, Aichi-ken (JP); Shigemi Horiuchi, Aichi-ken (JP); Masanobu Ando, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Toyoda Gosei Co., Ltd., Aichi-ken (JP)

(21) Appl. No.: 11/633,621

(22) Filed: Dec. 5, 2006

(30) Foreign Application Priority Data
Jun. 12, 2005 (JP) 2005-352726

(51) Int. Cl. H01L 29/792

(52) U.S. Cl. 257/324

(57) ABSTRACT

An object of the invention is to prevent defoliation of a first electrode layer of the device of the invention including a high-reflectance metal layer. In the group III nitride based compound semiconductor optical device of the invention, an electrode formed on a p-type layer has a first electrode layer which is formed from high-reflectance rhodium (Rh) and which is directly joined to the p-type layer, and a second electrode layer which is formed from titanium (Ti) having reactivity with nitrogen and which is provided so as to cover the first electrode layer, and a portion of the second electrode layer is joined to the uppermost layer of the group III nitride based compound semiconductor.

### BACKGROUND OF THE INVENTION

1. Field of the Invention

The present invention relates to a group III nitride based compound semiconductor optical device. As used herein, the term “semiconductor optical device” collectively refers to a semiconductor device having any. optical function of interest, including an energy conversion device for converting optical energy to electric energy or vice versa (e.g., a light-emitting device or a photoreceptor).

2. Background Art

It's been a long time since a group III nitride based compound semiconductor was found to be useful for producing a light-emitting device which emits green or blue light to UV light. Hitherto, such a light-emitting device has generally been produced through epitaxial growth of a group III nitride based compound semiconductor on an insulating hetero-substrate such as a sapphire substrate. Even when a conductive hetero-substrate is employed, considerable numbers of dislocations occurring during the growth remain in the formed epitaxial growth layer, which is problematic. In addition, while the epitaxial growth product is returned to ambient temperature, cracks attributed to difference in interlayer expansion coefficient are generated in a group III nitride based compound semiconductor layer, and the crack generation cannot be sufficiently prevented, which is also problematic.

Meanwhile, Japanese Patent No. 3418150, Japanese Kohyo Patent Publication Nos. 2001-501778 and 2005-522873, U.S. Pat. No. 6,071,795, and Kelly, et al., “Optical process for liftoff of group III-nitride films,” Physica Status Solidi (a) vol. 159 (1997), p. R3-R4 disclose some techniques for producing semiconductor devices employing a substrate for epitaxial growth and a supporting substrate for use in a device, which are different from each other. Specifically, a group III nitride based compound semiconductor layer is epitaxially grown on a first substrate, and the produced group III -nitride based compound semiconductor device is transferred to a second substrate.

### SUMMARY OF THE INVENTION

The present inventors have carried out extensive studies on employment of the above techniques for producing a group III nitride based compound semiconductor optical device. In the inventors' studies, a conductive substrate is employed as a supporting substrate, and an electrode bonded to a p-type layer being in contact with the supporting substrate is formed from a high-reflectance metal. In addition, on the opposite side, an electrode bonded to an n-type layer having a surface exposed through removal of a growth substrate is processed into a window frame form. Through employment of the inventors' technique, the light emitted from, for example, a group III nitride based compound semiconductor light-emitting device can be efficiently extracted through a window (i.e., area inside the window frame) where no frame-form electrode is provided on a surface of the n-type layer.

Meanwhile, in the case where a group III nitride based compound semiconductor layer is separated, through laser beam radiation, from the sapphire substrate on which the semiconductor layer has been grown, a semiconductor layer (e.g., GaN layer) is melted and decomposed to form droplets of Ga and N₂ gas in a melted region of the semiconductor layer. Pressure of N₂ in the form of bubbles and partial separation of the GaN layer from the substrate locally release inner stress of the GaN layer, whereby large stress is applied to areas adjacent (in the depth and in-plane directions) to the laser-beam-radiated region. In a current laser radiation technique, a wafer having a diameter of 5 to 12.5 cm cannot be irradiated in a single operation with a laser-beam and, instead, each unit area (e.g., a square measuring 2 to 3 mm×2 to 3 mm) is irradiated, with the laser beam scanning over the wafer. Since defoliation of the GaN layer from the substrate initiates at a site and is gradually spread, considerably large stress is applied to areas around the defoliated region. This stress is applied to the stacked body in the depth direction from the epitaxial layer to the supporting substrate (e.g., an n-type silicon substrate). In this case, since interlayer adhesion is the weakest between a p-type group III nitride based compound semiconductor layer and an electrode layer formed of high-reflectance metal, the metal electrode layer is defoliated from the p-type group III nitride based compound semiconductor layer.

The above problem is involved in separation of the grown group III nitride based compound semiconductor layer from the growth substrate through the laser lift-off technique.

In an attempt to solve the problem, an object of the present invention is to prevent defoliation of a high-reflectance metal layer during removal of a growth substrate.

According to a first aspect of the present invention, there is provided a group III nitride based compound semiconductor optical device including a group III nitride based compound semiconductor layer and at least one electrode formed on the semiconductor layer,

wherein said at least one electrode comprises a first electrode layer of high reflectance which is formed on the group III nitride based compound semiconductor layer, and a second electrode layer which is formed from a metal having reactivity with nitrogen and which is provided so as to cover the first electrode layer, and

a portion of the second electrode layer is joined to the group III nitride based compound semiconductor layer.

Through employment of the above structure, when a group III nitride based compound semiconductor is transferred to a supporting substrate, and a substrate on which the compound semiconductor is grown (hereinafter referred to as “growth substrate”) is removed from the semiconductor, defoliation of the first electrode layer can be effectively prevented. Although the compound semiconductor optical device of the present invention has the above electrode structure, the present invention is not limited to a semiconductor optical device which is produced through transferring an epitaxially grown semiconductor layer to a supporting substrate and removing the growth substrate. That is, no particular limitation is imposed on the method of producing the optical device of the present invention, so long as the optical device has a first electrode layer and a second electrode layer having the above structural feature. Thus, the first electrode layer is not necessarily joined to the supporting substrate.

In the case where a group III nitride based compound semiconductor is epitaxially grown on a growth substrate, the grown stacked structure generally has a layer configuration for facilitating p-type activation in which a layer proximal to the growth substrate assumes an n-type layer and a layer distal to the substrate (i.e., upper layer) assumes a p-type layer. Therefore, the first and second electrode layers are generally in contact with the p-type layer. However, if n-type upper layer can be produced through an improved technique, the first and second electrode layers may be in contact with the n-type layer. In a semiconductor optical device which is.produced through removal of a growth substrate from the semiconductor stacked structure, the first and second electrode layers are joined to the supporting substrate. The first electrode may be directly joined to the group III nitride based compound semiconductor layer. Alternatively the first electrode may be indirectly joined to the group III nitride based compound semiconductor layer through a transparent electrode such as a single or multi-layer of ITO or oxide formed on the group III nitride based compound semiconductor layer.

According to a second aspect of the present invention, the second electrode layer is joined to the group III nitride based compound semiconductor layer, at a region extending along and proximal to the outer periphery of the optical device (hereinafter referred to as “a device peripheral portion”).

The second electrode layer may be joined to the semiconductor layer over the entirety of the device peripheral portion of the optical device or over a part of the device peripheral portion.

According to a third aspect of the invention, the first electrode layer has a plurality of holes, and the second electrode layer is joined to the group III nitride based compound semiconductor layer, via the holes for providing contact.

No particular limitation is imposed on the positions of holes of the first electrode layer, and the holes may be provided at a uniform or non-uniform density over the layer, or in the center or the peripheral portion of the electrode layer. The hole density may be high in the peripheral portion and low in the center (or vice versa).

The structure of the second aspect in which the second electrode layer is joined to the semiconductor layer at an outer periphery of the first electrode may be combined with that of the third aspect in which the second electrode layer is joined to the semiconductor layer via the holes for providing contact.

According to a fourth aspect of the present invention, the first electrode has a plurality of regions mutually separated from one another, and the second electrode layer is joined to the group III nitride based compound semiconductor layer, at the peripheral region of said mutually separated regions.

That is, the first electrode layer is divided into a plurality of sections, and in each section, the second electrode layer is formed so as to join to the semiconductor layer at the peripheral portion.

According to a fifth aspect of the present invention, the first electrode layer is formed from iridium (Ir), platinum (Pt), rhodium (Rh), silver (Ag), an alloy including at least one thereof as a main component, or a multi-layer thereof. According to a sixth aspect of the present invention, the first electrode layer is a multi-layer, which includes at least a transparent electrode layer directly joined to the group III nitride based compound semiconductor layer and a high-reflectance metal layer. According to a seventh aspect of the present invention, the second electrode layer is formed from chromium (Cr), molybdenum (Mo), tantalum (Ta), titanium (Ti), vanadium (V), tungsten (W), an alloy including at least one thereof as a main component, or a multi-layer thereof.

The metal which readily forms a nitride thereof tends to be alloyed with a group III nitride based compound semiconductor layer, whereby remarkably high adhesion between the metal and the semiconductor can be attained. Therefore, a second electrode layer made of a metal which readily provides a non-insulating nitride thereof is formed so as to cover a first electrode layer formed from a high-reflectance metal or a first electrode layer including a high-reflectance metal in a stacked structure thereof. In such a structure, the second electrode layer is joined to a portion of the group III nitride based compound semiconductor layer. Therefore, the second electrode layer is securely joined to the group III nitride based compound semiconductor layer, and defoliation of the first electrode layer disposed therebetween caused by stress or other factors can be prevented. By virtue of the structure, there may be employed, for producing the optical device of the present invention, the aforementioned method for removing a growth substrate from an epitaxial growth layer through, for example, laser beam radiation so as to melt and decompose a GaN layer. In other words, there can be prevented defoliation of the first electrode layer from the semiconductor layer, which would otherwise be caused by large stress attributed to formation of Ga droplets and N₂ gas during laser irradiation at the interface between the growth substrate and the epitaxially grown semiconductor layer (first aspect).

When the second electrode layer is joined to the group III nitride based compound semiconductor layer at the peripheral portion of each of the separated devices, a predominant area of the first electrode layer including the center thereof can serve as an area for joining to the group III nitride based compound semiconductor layer. As a result, reflection of light emitted from a light-emitting region of a light-emitting device can be attained at remarkably high efficiency (second aspect).

The joining site is not limited to the peripheral portion of each device, and the second electrode layer may be joined to the group III nitride based compound semiconductor layer through a plurality of holes provided in the first electrode layer (third aspect). The first electrode may have a plurality of regions mutually separated from one another, and the second electrode layer may be joined to the group III nitride based compound semiconductor layer, at the peripheral region of said mutually separated regions (fourth aspect).

When the first electrode layer is formed-from a high-reflectance metal, iridium (Ir), platinum (Pt), rhodium (Rh), silver (Ag), an alloy including at least one thereof as a main component, or a multi-layer thereof is preferred (fifth aspect). In the case of a multi-layer, the first electrode layer preferably includes at least a transparent electrode and a high-reflectance metal layer (sixth aspect). The second electrode layer is preferably formed from a metal which provides a non-insulating nitride, the metal being chromium (Cr), molybdenum (Mo), tantalum (Ta), titanium (Ti), vanadium (V), tungsten (W), an alloy including at least one thereof as a main component, or a multi-layer thereof (seventh aspect).

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIGS. 1A to 1J show cross-sections of a group III nitride based compound semiconductor light-emitting device 1000 showing production steps therefor;

FIG. 2A is a plan view showing a first exemplary configuration of an Rh electrode 121 formed from a high-reflectance metal and a joint portion C between a titanium layer 122 and a p-type layer 12;

FIG. 2B is a plan view showing a second exemplary configuration of an Rh electrode 121 formed from a high-reflectance metal and a joint portion C between a titanium layer 122 and a p-type layer 12; and

FIG. 2C is a plan view showing a third exemplary configuration of an Rh electrode 121 formed from a high-reflectance metal and a joint portion C between a titanium layer 122 and a p-type layer 12.

### DETAILED DESCRIPTION OF PREFERRED EMBODIMENTS

The present invention is applicable to any type of group III nitride based compound semiconductor optical device, particularly to a light-emitting device having a light extraction region, and a photoreceptor having a light-accepting region. In the case of a semiconductor optical device having a supporting substrate, an electrode (e.g., a window-frame-shape electrode) is preferably formed, directly or by the mediation of a transparent electrode, on a group III nitride based compound semiconductor layer provided on a surface not being in contact with the supporting substrate. When positive and negative electrodes are provided so as to sandwich a light-emitting region, the supporting substrate is. preferably a conductive substrate.

In the case where a semiconductor layer is separated from an epitaxial growth substrate by melting and decomposing a semiconductor layer (e.g., a GaN thin film) through laser beam radiation, a laser beam having a wavelength shorter than 365 nm is preferably employed. Alternatively, YAG laser beams (wavelength: 365 nm and 266 nm), an XeCl laser beam (wavelength: 308 nm), an ArF laser beam (155 nm), and a KrF laser beam (wavelength: 248 nm) are preferably employed. The laser beam radiation area for one operation; i.e., a unit radiation area, may be a rectangular area having a size of integral multiples of a chip size, in both the lateral and transverse directions. For example, when a chip (square) has a side of 500 μm, an unit radiation area of 2 mm×2 mm, which corresponds to an area including 4×4 chips, may be employed. Alternatively, a unit radiation area of 3 mm×3 mm, which corresponds to an area including 6×6 chips, may be employed. Such a unit laser beam radiation area is continuously scanned on a wafer without overlapping radiation areas. Such operation is preferred, since contours of the unit radiation area do not remain in a chip area. In other words, a semiconductor-melted area and a semiconductor-non-melted area do not co-exist in one single chip area during one single laser beam radiation operation, whereby production yield and characteristics of devices can be enhanced.

The stacked structure of a group III nitride based compound semiconductor is preferably formed through epitaxial growth. A buffer layer, which is formed on a growth substrate prior to epitaxial growth, may be formed not through epitaxial growth but through other techniques such as sputtering. No particular limitation is imposed on the specific procedure of the growth method such as epitaxial growth, and no particular limitation is imposed on the type of the epitaxial growth substrate, layer configuration, layer structure of functional layers (MQW, SQW, cladding layer, guide layer, etc.) including a light-emitting layer, handling of divided devices, etc. Detailed descriptions of the layer structure and manufacturing method of the semiconductor stacked structure may be omitted in the Embodiment described hereinbelow. However, in the present invention, any of the structures and the techniques known at the time of the present application may be employed in combination. Unless otherwise mentioned, these known layer structures and techniques are incorporated into the present invention.

The term “group III nitride based compound” refers in a narrower sense to an AlGaInN-based 4-component (including 2-component and 3-component) semiconductor itself and, in a broader sense, to such a semiconductor to which a donor impurity element or an acceptor impurity element for imparting conductivity thereto has been added. However, in general, the above semiconductor compounds may further contain another group III element or group V element as an additional or substituted element, or may contain any additional element for imparting other functions thereto. These group III nitride based compounds are not excluded.

The electrode to be joined to the group III nitride based compound layer, and a single-layer or multi-layer electrode to be connected with the above electrode may be formed from any conductive material. Generally, a semiconductor optical device has a pair consisting of positive and negative electrodes. One key characteristic feature of the present invention is that one of the above electrodes is formed from a high-reflectance metal, thereby providing a first electrode layer whose structure is described in detail in relation to the aspects of the invention. When the electrode layer is formed from a metal layer and an oxide (e.g., ITO) layer, a dielectric layer formed of any dielectric material may be provided between the oxide layer and the metal layer in order to avoid direct contact therebetween. In this case, holes are provided in the dielectric layer, and the metal layer and the oxide (e.g., ITO) layer may be electrically connected through the holes, which are filled with conductive material.

The “other electrode” (i.e., counterpart of the above electrode), which is not a characteristic member of the present invention, is generally formed on a surface of a growth substrate. After removal of the growth substrate, the electrode is present on the exposed semiconductor layer. In general, the electrode is provided with respect to the n-type layer. It is a rare case that the counter electrode is provided on the entire surface of the semiconductor layer from a high-reflectance metal. However, the present invention does not exclude the counter electrode formed of a high-reflectance metal or a similar material. In fact, in the Embodiment given hereinbelow, an n-type electrode of a window frame shape is formed. In the n-type electrode, the first electrode layer may be covered with the second electrode layer, which is securely joined to the semiconductor layer. In other words, the n-type electrode may have the same joint structure as employed in the p-type electrode described in the Embodiment hereinbelow. In the case where the n-type electrode employs such a characteristic feature of the present invention, the p-type electrode does not necessarily employ the characteristic feature. In the case of an n-type electrode, the first electrode layer may be formed from a low-contact-resistance material instead of a high-reflectance metal, and the second electrode layer is provided so as to prevent defoliation of the first electrode layer. Depending on the design of the optical device, there may be employed any metallic material, alloy, and other conductive material, or a multi-layer thereof. When the counter electrode is to be formed on the entirety of the semiconductor layer, a transparent electrode may be employed. Examples of the transparent material include indium tin oxide, indium titanium oxide, and other oxide materials.

Needless to say, the first electrode layer of the present invention, which is generally provided with respect to a p-type layer, may be formed from an oxide electrode such as an indium tin oxide electrode or an indium titanium oxide electrode provided on the p-type layer, and a high-reflectance metal provided on the oxide electrode. In this case, the second electrode layer is securely joined to the p-type layer, whereby the oxide electrode and the high-reflectance metal electrode are securely fixed to the p-type layer.

The epitaxial growth wafer and the supporting substrate are preferably joined together by use of a solder. Depending on the composition of the solder, a multi-layer metal film is preferably provided, in accordance with needs, on the joint surface of the supporting substrate or the epitaxial growth wafer.

As also mentioned above, a characteristic feature of the present invention is the electrode structure, and other structures may be provided with any of known structures and techniques in combination.

### Embodiment 1

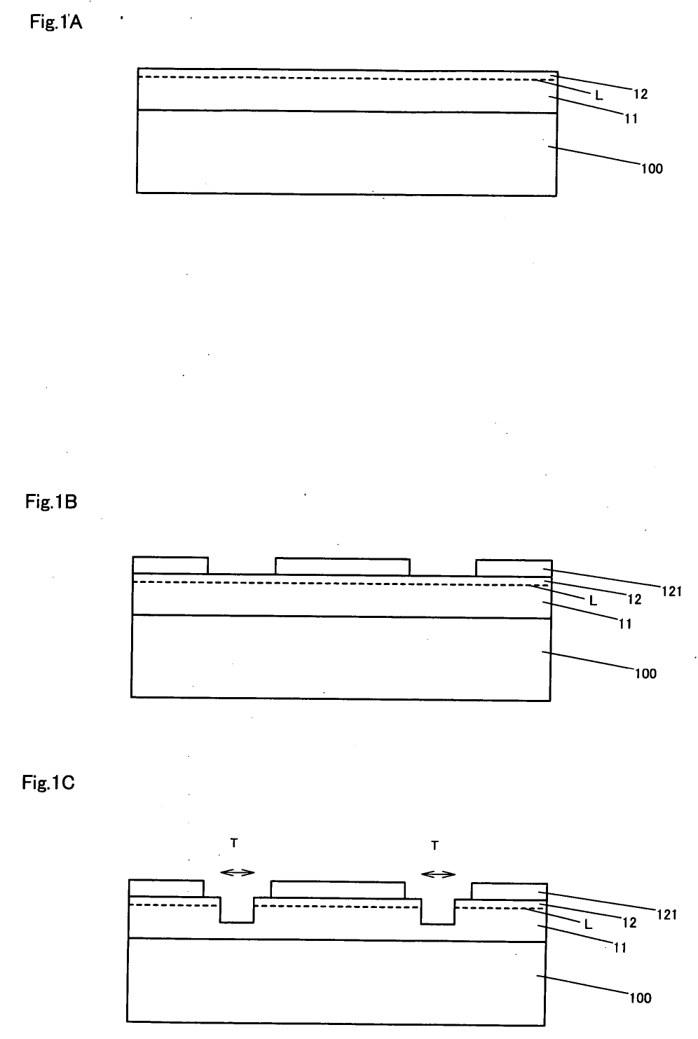

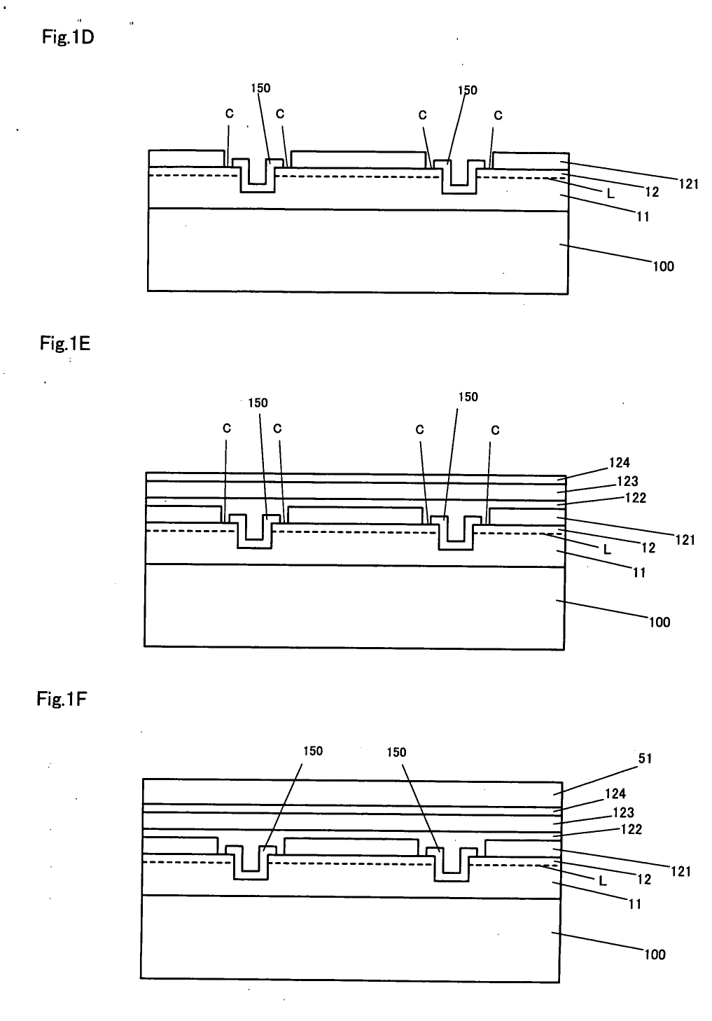

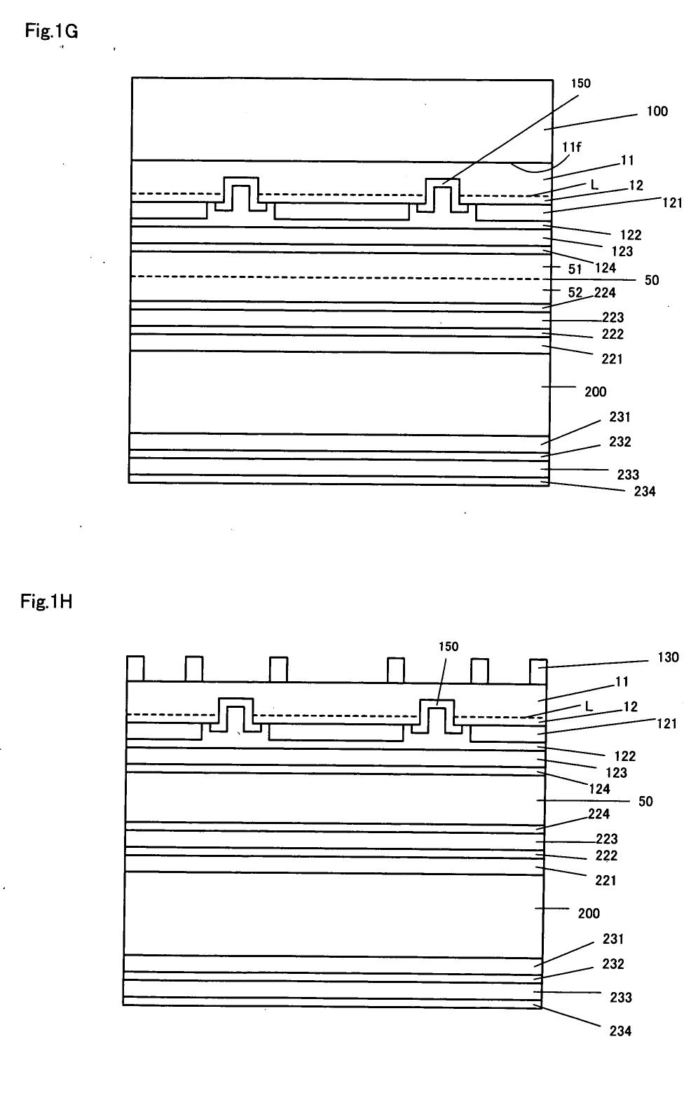

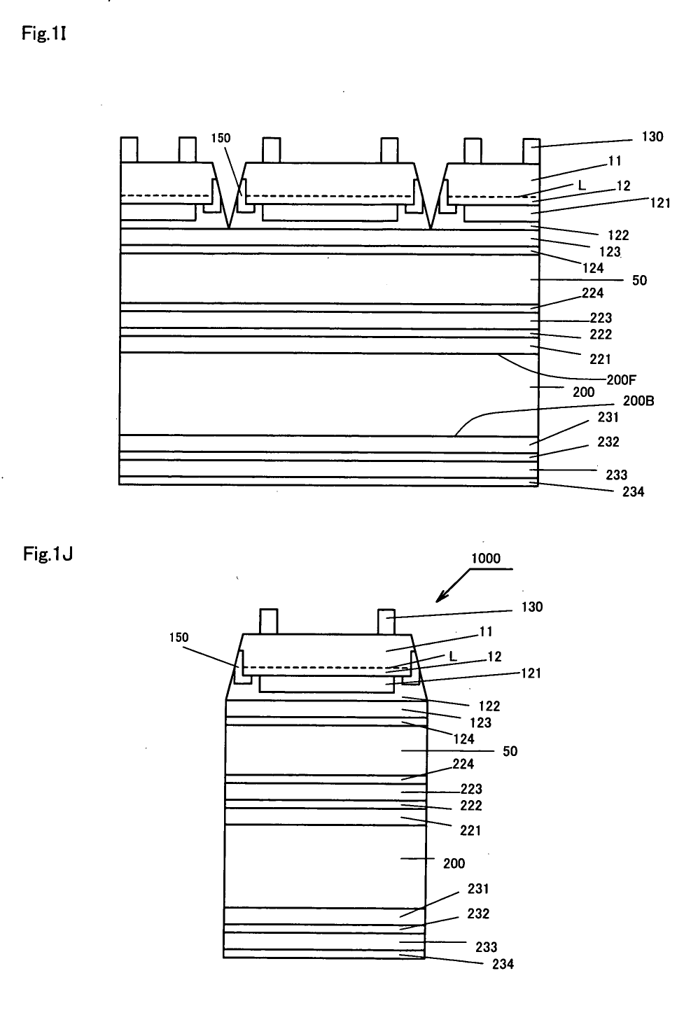

FIGS. 1A to 1J show cross-sections of a group III nitride based compound semiconductor light-emitting device 1000 in the production steps according to one embodiment of the present invention. FIG. 1J shows one chip of the group III nitride based compound semiconductor light-emitting device 1000. FIGS. 1A to 1I show cross-sections of about three chips of the device, and enlarged cross-sections of one single wafer.

Firstly, a sapphire substrate 100 is provided, and a group III nitride based compound semiconductor layer is formed on the substrate through routine epitaxial growth (FIG. 1A). FIG. 1A shows the group III nitride based compound semiconductor layer as a simplified stacked structure including an n-type layer 11 and a p-type layer 12 with a light-emitting region L. In FIGS. 1A to 1J, the n-type layer 11 and the p-type layer 12 are shown as two layers in contact with each other at the light-emitting region L represented by a broken line, and detailed stacked structures are not provided. For example, on the sapphire substrate 100, there is formed a stacked structure including a buffer layer, a silicon-doped GaN high-concentration n⁺layer, a GaN low-concentration n-type layer, and an n-AlGaN cladding layer, which are formed in this order. In this case, the stacked structure is represented by only the n-type layer 11 in FIGS. 1A to 1J. Similarly, a stacked structure including a magnesium-doped p-AlGaN cladding layer, a GaN low-concentration p-type layer, and a GaN high-concentration p⁺layer, which are formed in this order, is represented by only the p-type layer 12 in FIGS. 1A to 1J. The light-emitting region L, which is represented by a broken line, indicates both a pn-junction face and, for example, a multiple-quantum well light-emitting layer (well layers are generally undoped). Thus, the light-emitting region L does not simply represent the interface between the n-type layer 11 and the p-type layer 12. The “plane of the light-emitting region” refers to a plane present near the light-emitting region L represented by a broken line. Before performance of “the below-mentioned heat treatment under nitrogen (N₂) atmosphere,” the p-type layer 12 is a layer containing a p-type impurity element but electric resistance thereof is not lowered. After completion of “the heat treatment under nitrogen (N₂) atmosphere,” the p-type layer 12 is a general low-resistance p-type layer.

Subsequently, a patterned resist film is formed on the p-type layer 12, and a rhodium (Rh) film (thickness: 300 nm) was vapor-deposited over the resist film. The resist film is subjected to the lift-off process, to thereby form a patterned high-reflectance electrode 121, serving as a first electrode. Specifically, the rhodium (Rh) high-reflectance electrode 121 was formed to assume a square (420 μm×420 μm). The interval between the two adjacent rhodium (Rh) high-reflectance electrodes 121 was adjusted to 80 μm. Thus, a lattice-like exposed surface of the p-type layer 12 (line width: 80 μm) was provided (FIG. 1B). Subsequently, the thus-processed stacked body was heated at 570° C. under N₂ for three minutes, to thereby lower the resistance of the p-type layer 12 and lower the contact resistance of the p-type layer 12 and the rhodium (Rh) high-reflectance electrode 121.

The center of each line portion of the lattice-like exposed p-type layer 12, serving as a chip-cutting line, was etched (width: 20 μm, depth: 3 μm) to form a lattice-form trench T (FIG. 1C). The depth of the trench T was controlled such that the bottom of the trench T was located under the light-emitting region L and sufficiently penetrated the n-type layer 11.

Subsequently, the entire surface of the wafer including the trenches T is covered with a silicon oxide (SiO₂) film. Specifically, the silicon oxide (SiO₂) film was formed so as to cover at least the side surfaces of each trench T (surfaces normal to the growth substrate) and to have a thickness of 300 nm. Subsequently, a photomask (not illustrated) was provided on an area of the silicon oxide (SiO₂) film corresponding to the bottom and side surfaces of each trench T, and the portions of the silicon oxide (SiO₂) film not covered with the photomask were removed through dry etching. After removal of the photomask, an insulating film 150 formed of silicon oxide (SiO₂) was provided on and around the trenches T. Thus, on the surface of the p-type layer 12 which is in parallel to the main surface of the substrate, lattice-form exposed surfaces C having a line width of 20 μm and separated by the trenches T were formed (FIG. 1D). On the exposed surfaces C, neither the silicon oxide (SiO₂) insulating film 150 nor the rhodium (Rh) high-reflectance electrode 121 was formed. The exposed surface C serves as a contact portion with respect to a titanium layer serving as a second electrode layer.

Next will be described formation of a multi-layer metal film through vapor deposition. Specifically, a titanium (Ti) layer 122 (thickness: 50 nm) serving as the second electrode, a nickel (Ni) layer 123 (thickness: 500 nm), and a gold (Au) layer 124 (thickness: 50 nm) are sequentially formed; to thereby provide a layer structure as shown in FIG. lE. The functions of the titanium (Ti) layer 122, nickel (Ni) layer 123, and gold (Au) layer 124 are as follows. The gold (Au) layer 124 serves as a layer for alloying with a 20%-tin gold-tin solder (Au-20Sn) 51 to be provided. The nickel (Ni) layer 123 prevents migration of tin (Sn) to the rhodium (Rh) high-reflectance electrode 121. The titanium (Ti) layer 122 enhances adhesion with respect to the nickel (Ni) layer 123 and the exposed surfaces C of the p-type layer 12.

On the gold (Au) layer 124, a 20%-tin gold-tin solder (Au-20Sn) layer 51 having a thickness of 3,000 nm is provided (FIG. 1F).

Next, an n-type silicon substrate 200 serving as a supporting substrate is provided. On each surface of the substrate, a multi-layer conductive film is formed through vapor deposition or a similar process. Specifically, layers to be formed on the surface of supporting substrate which is joined to the gold-tin solder (Au-20Sn) 51 (hereinafter referred to as a front surface) are denoted by reference numerals 221 to 224, and layers to be formed on the back surface of the substrate are denoted by reference numerals 231 to 244. On each surface of the silicon substrate 200, a titanium nitride (TiN) layer (thickness: 30 nm) 221 or 231, a titanium (Ti) layer (thickness: 50 nm) 222 or 232, a nickel (Ni) layer (thickness 500 nm) 223 or 233, and a gold (Au) layer (thickness: 50 nm) 224 or 234 were formed. The titanium nitride (TiN) layers 221 and.231 are employed by virtue of low contact resistance with respect to the n-type silicon substrate 200. The functions of the titanium (Ti) layers 222 and 232, those of the nickel (Ni) layers 223 and 233, and those of the gold (Au) layers 224 and 234 are completely the same as those of the aforementioned titanium (Ti) layer 122, nickel (Ni) layer 123, and gold (Au) layer 124, respectively. On the gold (Au) layer 224, serving as the uppermost layer of the multi-layer conductive film provided on the front surface of the n-type silicon substrate 200, a 20%-tin gold-tin solder (Au-20Sn) layer 52 having a thickness of 3,000 nm was formed. The tin 20% gold-tin solder (Au-20Sn) 51 shown in FIG. 1F is joined to the gold-tin solder (Au-20Sn) 52, whereby the wafer of the group III nitride based compound semiconductor light-emitting device is joined to the n-type silicon substrate 200. Through hot-pressing at 300° C. and 30 kgf/cm² (2.94 MPa), the two wafers are combined. Hereinafter, the gold-tin solder (Au-20Sn) will be denoted by reference numeral 50 as a unified layer (FIG. 1G).

The sapphire substrate 100 of the thus-combined wafer is irradiated with a KrF high-power pulse laser beam (248 nm). The employed irradiation conditions were an energy density of 0.7 J/cm² or higher, a pulse width of 25 ns, a unit radiation area of 2 mm×2 mm or 3 mm×3 mm, and a scanning period in the transverse direction of 10 Hz. In order to prevent overlapping of unit radiation areas, the laser beam was continuously scanned over the sapphire substrate 100. Timing of each radiation operation is determined such that contours of the unit radiation area do not exist in a single device chip. In other words, a contour of the unit radiation area is preferably present in a trench T, which is a chip separation region. Through the laser radiation, the interface 11f between the n-type layer 11 (GaN layer) and the sapphire substrate 100 is melted in the form of thin film, to thereby decompose to form gallium (Ga) droplets and nitrogen (N₂). Thereafter, the sapphire substrate 100 is removed through the lift-off process from the combined wafer. The thus-exposed surface of the n-type layer 11 is washed with dilute hydrochloric acid, to thereby remove gallium (Ga) droplets deposited on the surface.

In the subsequent step, a resist film (not illustrated) is formed over the exposed surface of the n-type layer 11. Through photolithography, the resist film is patterned to form the window portion of each device chip surrounded by a groove of a window frame shape. On the window frame groove of the resist film, a multi-layer metal film serving as an n-type electrode 130 is formed through vapor deposition. Specifically, on the n-type layer 11, a vanadium (V) layer (thickness: 15 nm), an aluminum (Al) layer (thickness: 150 nm), a titanium (Ti) layer (thickness: 30 nm), a nickel (Ni) layer (thickness: 500 nm), and a gold (Au) layer (thickness: 500 nm) were sequentially formed. Thereafter, the resist was removed through the lift-off process, to thereby leave an n-type electrode 130 formed of a multi-layer metal film in the window frame of the resist film. In this process, the remaining metal film is removed with the resist. On each surface of the n-type silicon substrate 200, a conductive multi-layer film is formed. Thus, the produced light-emitting device has the n-type silicon substrate 200 serving as a supporting substrate; a high-reflectance metal (rhodium (Rh)) layer 121 serving as a first electrode layer on the p-type layer 12; a titanium layer 122 serving as a second electrode layer which is formed on the layer 121 and which is partially joined to the p-type layer 12; and a multi-layer metal film formed on the second electrode layer. The p-type layer 12 is electrically connected, via the multi-layer metal film by the mediation of the gold-tin solder (Au-20Sn) 50, to the n-type silicon substrate 200 (FIG. 1H).

Subsequently, the n-type layer 11 is half-cut, by means of a dicing blade, at least to the depth so as to cut the silicon oxide (SiO₂) insulating film 150 formed at the bottom of the trench T. The half-cutting is not necessarily performed on the front surface 200F of the silicon substrate 200 (FIG. 1I). Subsequently, the silicon substrate 200 is also half-cut, by means of a dicing blade, on the back surface 200B where no group III nitride based compound semiconductor light-emitting layer is provided. Through breaking, respective group III nitride based compound semiconductor light-emitting devices 1000 are produced (FIG. 1J). Each group III nitride based compound semiconductor light-emitting device 1000 has a frame-form n-type electrode 130 at the periphery of the n-type layer 11, and the center area of the layer has a light-extraction area on the n-type side. The p-type electrode is electrically connected to the back surface 200 B of the silicon substrate 200 through the silicon substrate 200.

[Variant plane configurations of an Rh electrode 121 formed from a high-reflectance metal and a joint portion C between a titanium layer 122 and a p-type layer 12]

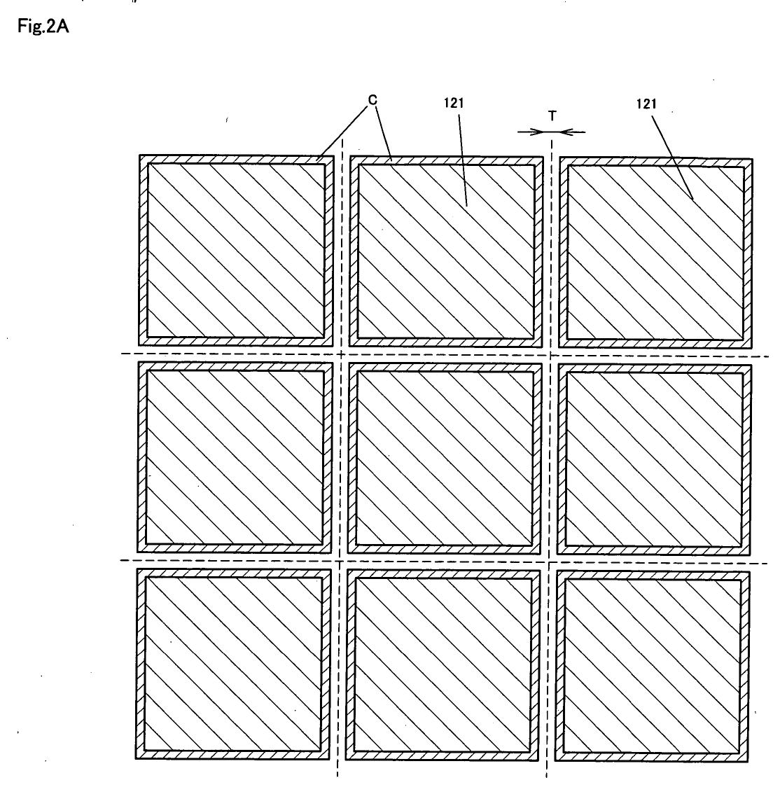

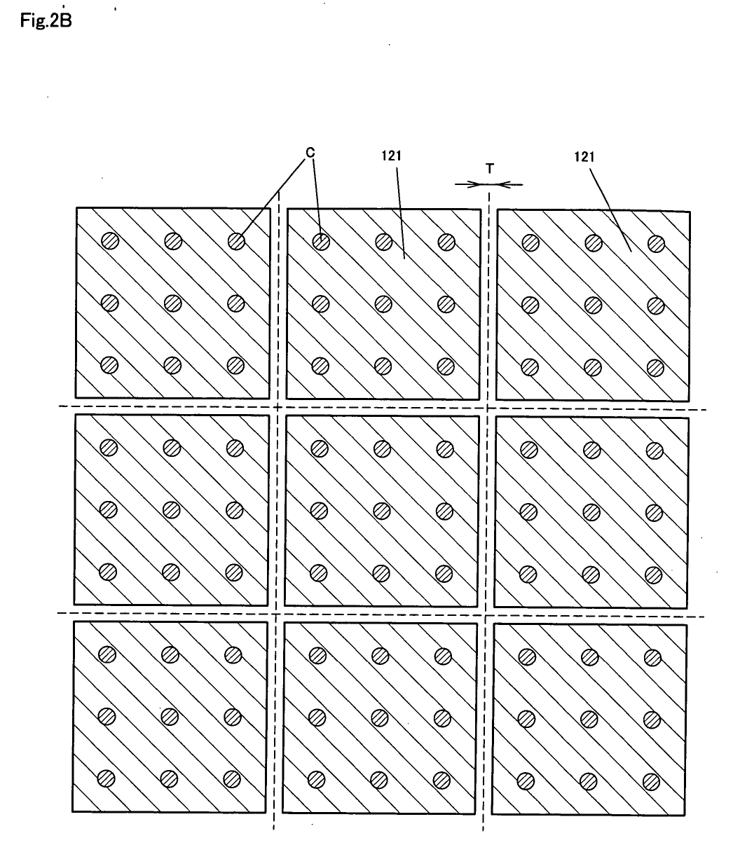

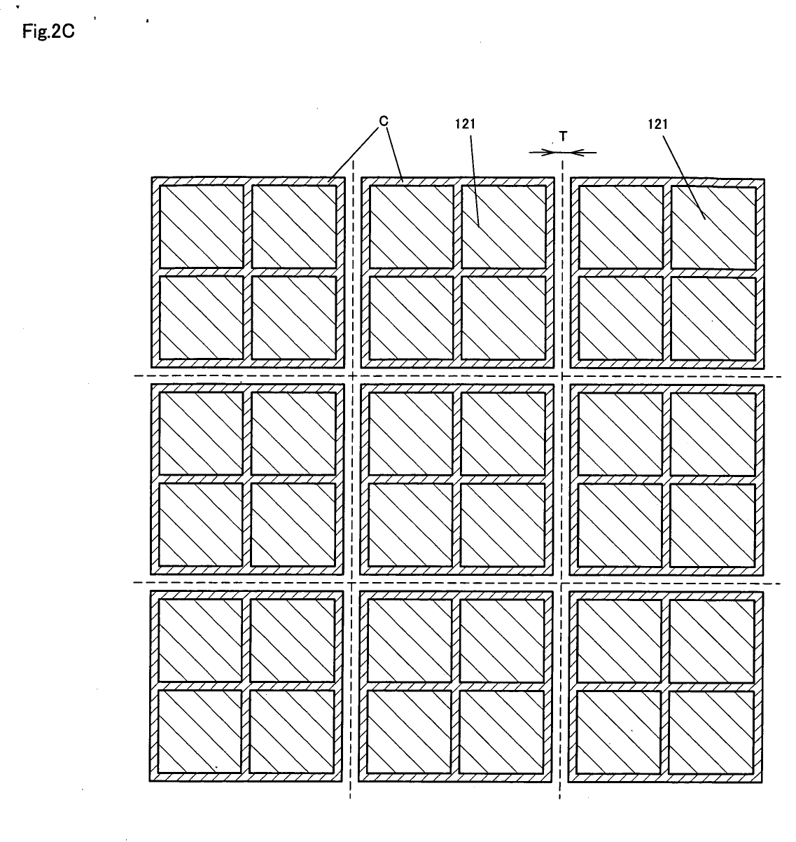

In Embodiment 1, the Rh electrode (first electrode) 121 formed from a high-reflectance metal and joint portions C between the titanium layer (second electrode) 122 and the p-type layer 12 (see FIGS. 1C and 1D) have a plane configuration as shown in FIG. 2A. In each device, one square Rh electrode 121 is surrounded by a joint portion C. In FIG. 2A, T denotes a trench, and illustration of the SiO₂ insulating film 150 is omitted. The Rh electrode 121 formed from a high-reflectance metal and joint portions C between the titanium layer 122 and the p-type layer 12 may have a plane configuration as shown in FIG. 2B or 2C. The joint portions C may be a plurality of holes provided in the Rh electrode 121 of one chip as shown in FIG. 2B. Alternatively, the Rh electrode 121 in each chip region may be divided into a plurality of portions, and the device peripheral portion of each Rh electrode 121 may serve as the joint portion C.

In FIG. 2B, the joint portions C are not necessarily provided at the device chip periphery portions. However, alternatively, the configuration of FIG. 2A and that of FIG. 2B may be combined. That is, a joint portion C of the frame shape may be provided at the device chip periphery, and dot-pattern joint portions C may be provided in the entire device chip region. In the case where no trench T is provided, no device chip unit is present during laser beam radiation. In this case, if contours of a unit laser beam radiation area cross the chip area, no detrimental problem occurs. However, in a preferred mode, the contours of a unit radiation area coincide with the dicing lines.

In Embodiment 1, instead of the Rh electrode 121, the first electrode layer may be formed from, for example, a reflective electrode having a three-layer structure including an indium tin oxide (ITO) transparent electrode formed on the p-type layer 12; a dielectric layer formed on the electrode, the layer having holes filled with a conductive material such as nickel; and a high-reflectance metal (e.g., aluminum or silver) layer formed on the dielectric layer. Alternatively the first electrode layer may be formed from a two-layer structure including an indium tin oxide (ITO) transparent electrode formed on the p-layer 12 and a high-reflection metal (e.g., aluminum or silver)

In Embodiment 1, trenches T and the SiO₂ insulating film 150 are formed. However, it may be the case that no trench or insulating film is formed before dicing.

In Embodiment 1, the n-type electrode 130 is directly formed on the n-type layer 11. However, a window-frame-form n-type electrode may be formed after formation of, for example, a transparent electrode.

In Embodiment 1, the first electrode layer 121 may be formed from iridium (Ir), platinum (Pt), silver (Ag), aluminum (Al), palladium (Pd), an alloy including at least one thereof as a main component, or a multi-layer thereof other than rhodium (Rh).

In Embodiment 1, the second electrode layer 122 is formed from chromium (Cr), molybdenum (Mo), tantalum (Ta), vanadium (V), tungsten (W), an alloy including at least one thereof as a main component, or a multi-layer thereof other than titanium (Ti).

What is claimed is:

1. A group III nitride based compound semiconductor optical device including a group III nitride based compound semiconductor layer and at least one electrode formed on the semiconductor layer,
wherein said at least one electrode comprises a first electrode layer of high reflectance which is formed on the group III nitride based compound semiconductor layer, and a second electrode layer which is formed from a metal having reactivity with nitrogen and which is provided so as to cover the first electrode layer, and
a portion of the second electrode layer is joined to the group III nitride based compound semiconductor layer.

2. A group III nitride based compound semiconductor optical device as described in claim 1, wherein the second electrode layer is joined to the group III nitride based compound semiconductor layer, at a device peripheral portion.

3. A group III nitride based compound semiconductor optical device as described in claim 1, wherein the first electrode layer has a plurality of holes, and the second electrode layer is joined to the group III nitride based compound semiconductor layer, via the holes for providing contact.

4. A group III nitride based compound semiconductor optical device as described in claim 2, wherein the first electrode layer has a plurality of holes, and the second electrode layer is joined to the group III nitride based compound semiconductor layer, via the holes for providing contact.

5. A group III nitride based compound semiconductor optical device as described in claim 1, wherein the first electrode layer has a plurality of regions mutually separated from one another, and the second electrode layer is joined to the group III nitride based compound semiconductor layer, at the peripheral region of said mutually separated regions.

6. A group III nitride based compound semiconductor optical device as described in claim 2, wherein the first electrode layer has a plurality of regions mutually separated from one another, and the second electrode layer is joined to the group III nitride based compound semiconductor layer, at the peripheral region of said mutually separated regions.

7. A group III nitride based compound semiconductor optical device as described in claim 3, wherein the first electrode layer has a plurality of regions mutually separated from one another, and the second electrode layer is joined to the group III nitride based compound semiconductor layer, at the peripheral region of said mutually separated regions.

8. A group III nitride based compound semiconductor optical device as described in claim 1, wherein the first electrode layer is formed from iridium (Ir), platinum (Pt), rhodium (Rh), silver (Ag), an alloy including at least one thereof as a main component, or a multi-layer thereof.

9. A group III nitride based compound semiconductor optical device as described in claim 2, wherein the first electrode layer is formed from iridium (Ir), platinum (Pt), rhodium (Rh), silver (Ag), an alloy including at least one thereof as a main component, or a multi-layer thereof.

10. A group III nitride based compound semiconductor optical device as described in claim 3, wherein the first electrode layer is formed from iridium (Ir), platinum (Pt), rhodium (Rh), silver (Ag), an alloy including at least one thereof as a main component, or a multi-layer thereof.

11. A group III nitride based compound semiconductor optical device as described in claim 1, wherein the first electrode layer is a multi-layer, which includes at least a transparent electrode layer directly joined to the group III nitride based compound semiconductor layer and a high-reflectance metal layer.

12. A group III nitride based compound semiconductor optical device as described in claim 2, wherein the first electrode layer is a multi-layer, which includes at least a transparent electrode layer directly joined to the group III nitride based compound semiconductor layer and a high-reflectance metal layer.

13. A group III nitride based compound semiconductor optical device as described in claim 3, wherein the first electrode layer is a multi-layer, which includes at least a transparent electrode layer directly joined to the group III nitride based compound semiconductor layer and a high-reflectance metal layer.

14. A group III nitride based compound semiconductor optical device as described in claim 1, wherein the second electrode layer is formed from chromium (Cr), molybdenum (Mo), tantalum (Ta), titanium (Ti), vanadium (V), tungsten (W), an alloy including at least one thereof as a main component, or a multi-layer thereof.

15. A group III nitride based compound semiconductor optical device as described in claim 2, wherein the second electrode layer is formed from chromium (Cr), molybdenum (Mo), tantalum (Ta), titanium (Ti), vanadium (V), tungsten (W), an alloy including at least one thereof as a main component, or a multi-layer thereof.

16. A group III nitride based compound semiconductor optical device as described in claim 3, wherein the second electrode layer is formed from chromium (Cr), molybdenum (Mo), tantalum (Ta), titanium (Ti), vanadium (V), tungsten (W), an alloy including at least one thereof as a main component, or a multi-layer thereof.
